(19) United States
(12) Patent Application Publication
(10) Pub. No.: US 2014/0093097 A1
(43) Pub. Date: Apr. 3, 2014

(54) Amplifying loudspeaker apparatus

(71) Applicant: MICHAEL WEIBIN ZHANG, Yuen Long (HK)

(72) Inventor: MICHAEL WEIBIN ZHANG, Yuen Long (HK)

(21) Appl. No.: 13/633,153

(22) Filed: Oct. 2, 2012

(51) Int. Cl. H03G 3/00

(52) U.S. Cl. CPC H03G 3/00
USPC 381/103

(57) ABSTRACT

An amplifying loudspeaker apparatus for an existing host device comprises a sensor coil for receiving an audio signal in electromagnetic form from an internal loudspeaker of the host device; a pre-amplifier and equalizer module connected to the sensor coil for amplifying and equalizing the audio signal to a suitable level and frequency response; and an audio power amplifier and a loudspeaker to reproduce the sound for the audio signal.

### CROSS REFERENCE TO RELATED APPLICATIONS

This application is based on and claims the priority of provisional patent application No. U.S. 61/629,888 filed Dec. 1, 2011.

### TECHNICAL FIELD

The present invention relates to short range audio transmission systems. More particularly, the present invention relates to short range inductively coupled audio transmission systems of an accessory device for a portable host device.

### BACKGROUND

Portable electronic devices such as mobile phones and tablet computers normally have built-in loudspeakers. Due to the limitation of the sizes, the built-in loudspeakers are often small and low in volume. Amplifying loudspeakers are often used as the accessory for these portable devices. Audio signals are normally transmitted to the amplifying speaker via a wired connector or standard digital wireless connection such as Wi-Fi or Bluetooth.

A standard digital wireless communication requires relatively complex circuitry and high power consumption, adding the cost to the accessory. A wired connection requires a physical connector which increases the size of the accessory and creates inconveniences when reconnecting and disconnecting. There is a need for a simpler and more cost effective wireless audio transmission mean to be used in some amplifying loudspeakers.

Inductive audio coupling has been known and used for a long time in the art.

Inductive audio coupling is used in hearing aid devices such as the T-Coil and audio-frequency induction loops (AFILs). Some short range audio broadcasting systems used in museums also use audio induction loops. In these applications, both the transmitter and receiver have to be designed in the first place with built-in components for inductive coupling.

Another inductive audio coupling device is the telephone pickup coil that has been used to pick up the audio signal from the transducer of a traditional telephone handset. The pickup coils have a limited frequency response and are limited to be used for hands-free operation, telephone recording, monitoring, and spying devices.

Some inductive audio pickups are used by musicians alike to receive and record audio frequency electromagnetic signals from the environment.

Inductive sensors and amplifiers are also used in measurement and testing equipments to pick up signals from electrical wires such as a telephone line.

The current invention uses inductive audio coupling to pick up audio signal from the built-in small loudspeakers of a ready-made mobile device to feed into an amplifying loudspeaker.

### SUMMARY OF THE INVENTION

The present invention provides an amplifying loudspeaker accessory for ready-made portable devices with built-in loudspeakers.

Most of host portable devices have a least one built-in loudspeaker for audio output. The built-in loudspeaker is normally a moving-coil transducer that produces an electromagnetic field during its operation. The accessory device related to the present invention has a sensor coil which is positioned closely to the host device's built-in loudspeaker to receive the electromagnetic audio signal. The received audio signal is used as the input of an amplifying loudspeaker system.

Because host devices are ready made products, the position and the maximum strength of the electromagnetic field of the loudspeaker are fixed for each model. The sensor coil of the accessory device related to the present invention is positioned closely to the loudspeaker to obtain a high enough signal-to-noise ratio.

The signal received by the sensor coil can also be used for control and data transmission as described in another patent application with the same assignee of the current application.

An apparatus for an amplifying loudspeaker according to the current invention includes a sensor coil, a pre-amplifier and equalizer module, an audio amplifier and loudspeaker module, a CPU module, and an input and output module.

One of the embodiments for the current invention is a wireless speaker for mobile phones and mobile media players.

### BRIEF DESCRIPTION OF THE DRAWINGS

FIG. 1 is a block diagram showing the wireless speaker of the present invention.

FIG. 2 describes a preferred embodiment as a portable wireless amplifying speaker for mobile phones and media players.

FIG. 3 is a block diagram showing a structure of the current invention that includes multiple sensor coils.

FIG. 4 is a block diagram showing manual switching for multiple sensor coils.

FIG. 5 is a block diagram showing an automatic switching mechanism for multiple sensor coil selection.

FIG. 6 describes a preferred embodiment as an amplifying speaker stand for a tablet computer.

FIG. 7 describes a structure to support both portrait and landscape positioning of the host device.

FIG. 8 describes a preferred embodiment as a hands-free car kit for mobile phones.

FIG. 9 is a block diagram showing a host device with a dedicated built-in transmitter coil.

FIG. 10 describes a preferred embodiment in which a transmitter coil is added in the accessory device.

FIG. 11 is a block diagram showing that a noise cancellation coil is added.

### DETAILED DESCRIPTION

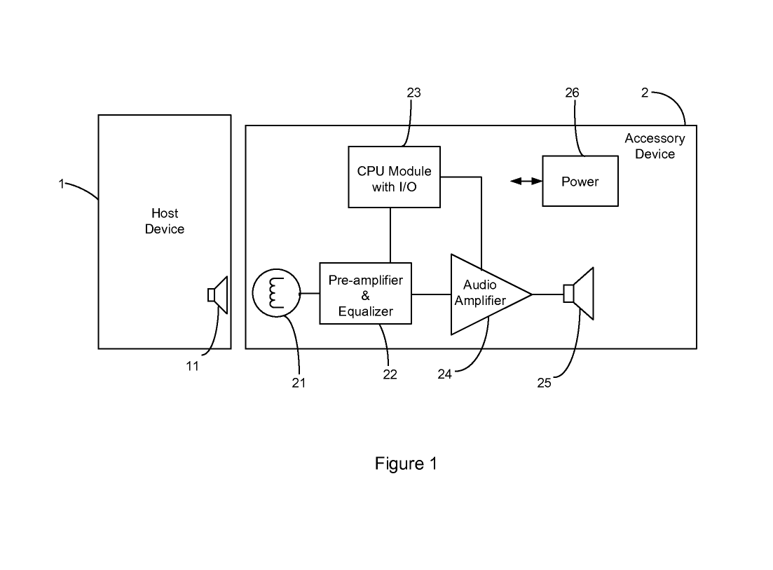

FIG. 1 describes an embodiment of the current invention that serves as a wireless speaker accessory 2 to work with a host device 2.

The host 1 is a portable device with at least one built-in speaker such as a mobile phone, audio/video player, portable gaming console or computer. The host 1 is essentially a computer system that is capable of producing sound as one of its outputs. The accessory device 2 comprises a sensor coil 21, a pre amplifier and equalizer 22, an audio amplifier 24 and at least one loudspeaker 25, a CPU module 23 with input and output interfaces, and a power module 26.

The host device 1 is a ready made product with at least one built-in loudspeaker 11 positioned at a fixed location inside the host 1. The sensor coil 21 inside the accessory is placed near the loudspeaker 11 in order to receive the maximum amount of electromagnetic signal generated by the coil inside the loudspeaker 11. The pre-amplifier 22 amplifies the signal from the sensor coil 21 to be suitable for the audio amplifier 24. The equalizer is essential one or more filters to compensate the frequency response of the entire system so as to produce better quality sound.

Normal audio signals are amplified by the audio amplifier 24 and output to loudspeaker 25 to be heard by the user. By positioning the host device 1 on the right place on the accessory 2, the sound from the host device 1 is significantly amplified without the needs of altering and adjusting any software or hardware inside the host device 1.

CPU module 23 with input and output interfaces are mainly used for control of the accessory 2. The input and output interfaces include switches or lights that are used to control and display the status of the accessory, such as power on/off, and volume adjustment.

The CPU module 23 can serve as power management controller for the accessory 2. The control functions include turn on and off the audio amplifier 24 automatically. When the sound playing host device 1 is in position with the accessory 2, the CPU module receives 23 the sensed signals from the pre-amplifier 22 and analyses the signals to determine sound or music is being played. The CPU module 23 then sends the corresponding control signal to enable or power up the audio amplifier 24. When the host 2 stops playing sound or is moved away from the correct position, the CPU module 23 can detect this status and disable or power down the audio amplifier 24.

The audio signal picked up from loudspeaker 11 of host 1 can be normal sound, voice or music, or encoded audio signal such as DTMF tones generated by the host's existing functionality such as dialing. A software package designed to work with the accessory 2 can also be installed in host 1 to generate encoded signals to be received by sensor coil 21 and processed by CPU module 23. The encoded signals can carry controlling commands for the accessory such as volume up or down, mute, equalizer adjustment. These controlling signals can be decoded by the CPU module 23 and used to control the pre-amplifier and equalizer 22, audio amplifier 24, and other modules in the accessory.

As the loudspeaker 11 inside the host 1 has not been designed to be used as a transmission device for the accessory, the frequency response for this sensor coil/loudspeaker coupling is not uniform for most types of host device. Often the low frequency signals are prevented from going to the loudspeaker 11 of the host 1 because of the small size of the loudspeaker 11. The sensor coil 21 is designed to receive the most signals from the loudspeaker 11. The pre-amplifier and equalizer 22 compensate for this and allow the overall audio system to have a flatter frequency response. A digital signal processor (DSP) that serves as a precise equalizer can help to achieve a better frequency response. The DSP can also regenerate or simulate the low frequency signals that are cut off before sending to the loudspeaker 11.

Digital signal processing means can also be applied to an added music playback software package inside the host device 1 to compress the music into a frequency range that is suitable to be transmitted via the existing host device 1. The DSP inside the pre-amplifier 22 then decompress the music to reproduce the music.

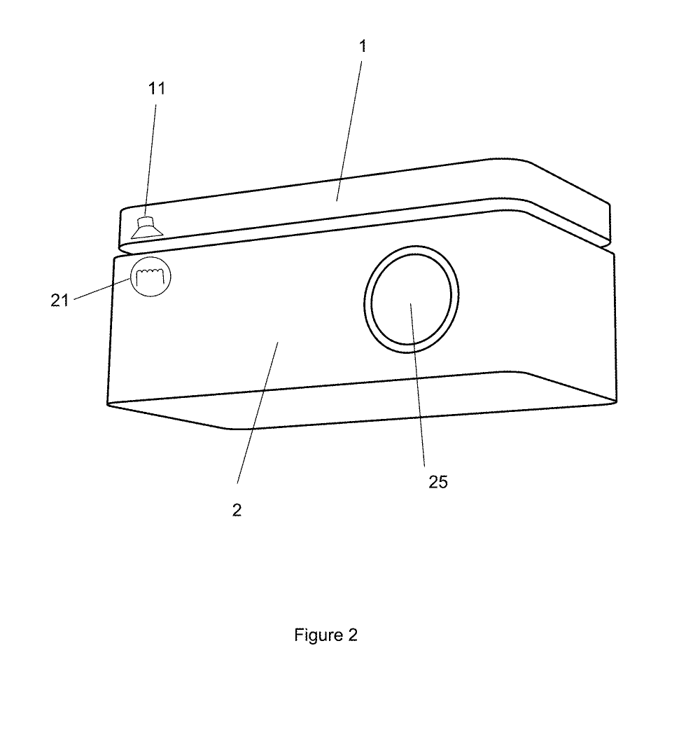

FIG. 2 describes a preferred embodiment as a portable wireless amplifying speaker for mobile phones and media player.

The accessory device 2 has a form of a small stereo amplifying speaker. The host device 1 can be a mobile phone or mobile media player such as an iPhone. The sensor coil 21 inside the amplifying speaker 2 is located beneath the top surface. The host device 1 can rest on top of the amplifying speaker 2. Sound from the host device 1 is picked up and amplified by the amplifying speaker 2. The locations of the built-in speaker or speakers of different models of host devices are different.

For some host devices 1, the position of the host device 1 related to the amplifying speaker 2 may need to be adjusted so that the loudspeaker 11 is right on top of the sensor coil 21. This adjustment action may be viewed by some end users as troublesome and the final position may not be symmetrical. To improve on this, multiple sensor coils can be placed in the selected position to make the amplifying speaker 2 more compatible with more host devices.

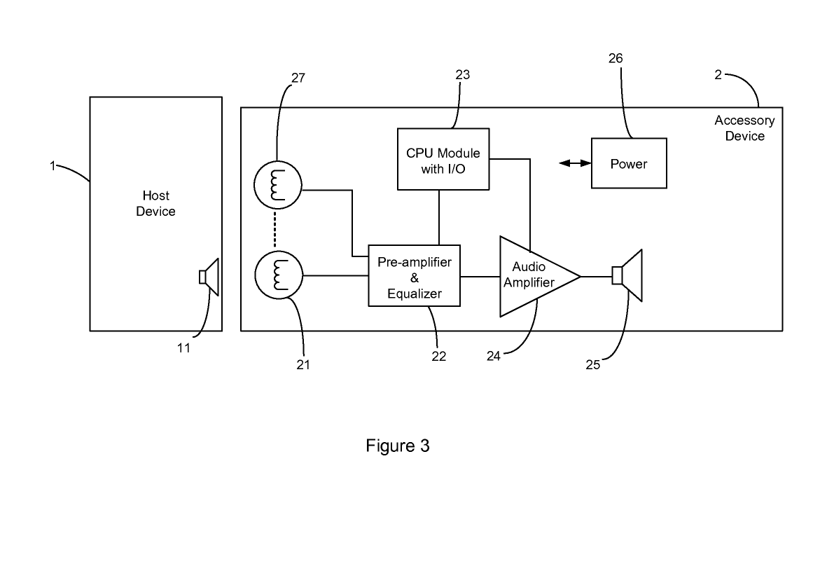

FIG. 3 describes a preferred embodiment of the current invention that includes multiple sensor coils. One or more extra sensor coils 27 are placed in positions that suit as many existing host devices as possible to allow maximum compatibility. When a certain type of host 1 is put on top of the accessory device 2, one or more of the sensor coils will match the speaker or speakers of the host 1. The matched sensor coil or coils will pick up the audio signals from the host 1 and pass them to the pre-amplifier.

As sensor coils can also pick up other electromagnetic signals which are often present near the host device, too many sensor coils that are working in parallel can introduce too much unwanted noise.

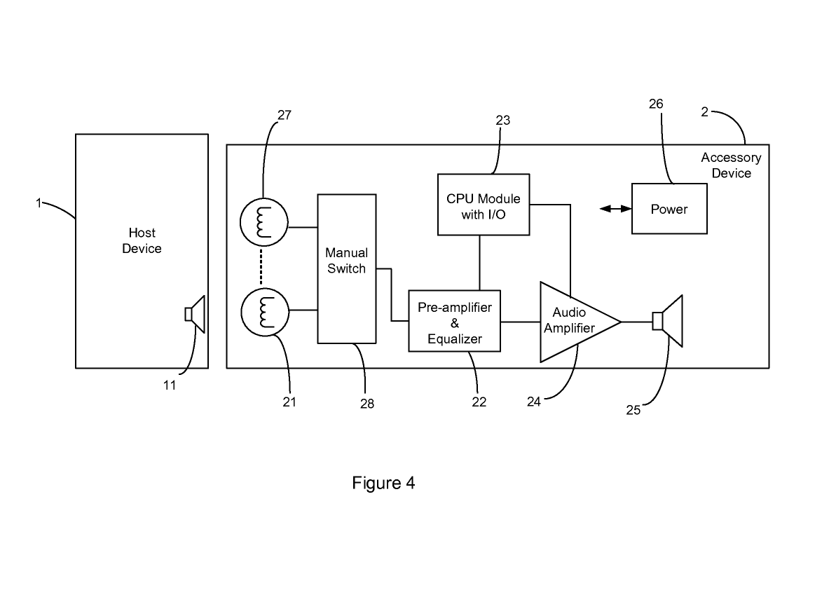

As described in FIG. 4, manual switches 28 are added to connect only the sensor coils that are useful for a certain model of host device 1 to the pre-amplifier 22. When choosing the right switch position, the user can place the host device 1 with music playing in position with the accessory device 2 to try for the most suitable switch setting. However, this manual switch approach may be viewed by some users as troublesome.

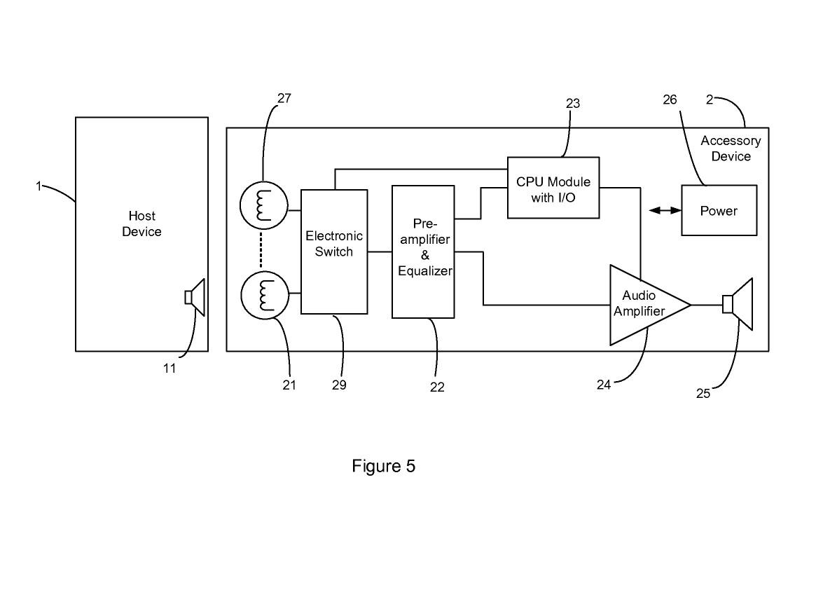

FIG. 5 describes an automatic switching mechanism for multiple sensor coil selection. Each sensor coil 21 is connected to the pre-amplifier 30 via an electronic switch 29 that is controlled by the CPU module 23. During the automatic configuration process, the electronic switch 29 is enabled one by one in turn by the CPU module 23 for the CPU module 23 to detect which sensor coil is receiving strong music signals. When all the sensors coils have been scanned, the CPU will determine which sensor coils are receiving the useful audio signal and which sensor coils are receiving interference or no signal. The electronic switches for the sensor coils that are receiving useful audio signal will be turned on as the result of the automatic configuration process.

The automatic configuration process can be started manually by the end user pressing a button. The automatic configuration process can also be started automatically each time when a music playing session begins. This is useful as the accessory device can be shared by different users with different host device. Quick and automatic configuration is one of the advantages of the current invention.

Another embodiment of the current invention allows the sensor coil(s) to be repositioned physically to suit different host devices. A smaller number of sensor coils will be needed than the multiple sensor coil approach. Different mechanical structures and designs can be used to allow the users to adjust the position of the sensors coils to match their particular type of host device. The mechanism and structure are also be used to keep the host and accessory in position relating to each other. For example, the accessory device can be a speaker stand for a tablet computer such as the iPad that not only amplifies the sound but also supports the iPad in the right positions for being used or viewed by the user.

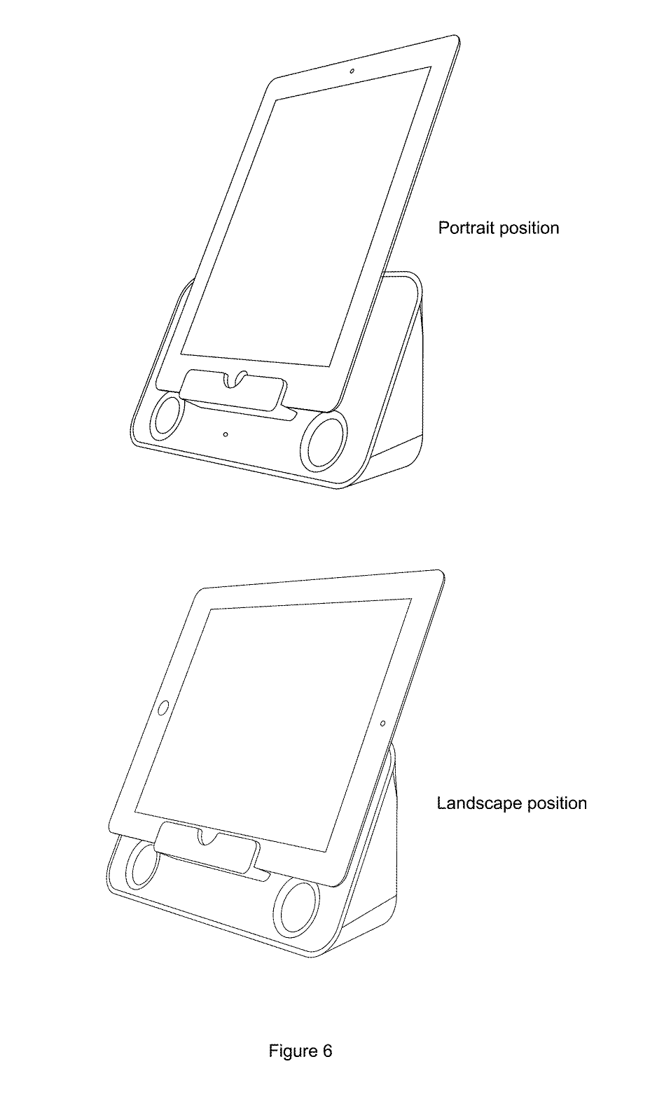

FIG. 6 describes a preferred embodiment as a speaker stand for a tablet computer such as the iPad from Apple. The stand can support the host device in both portrait and landscape positions. In different positions, the locations of the speakers of the host device related to the speaker stand are different.

Multiple sensors can be placed inside one accessory device to match the same host device for different kinds of positioning. For example, a set of sensor coils can be placed to support the portrait positioning of the host and another set of sensor coils can be placed to support the landscape positioning of the host.

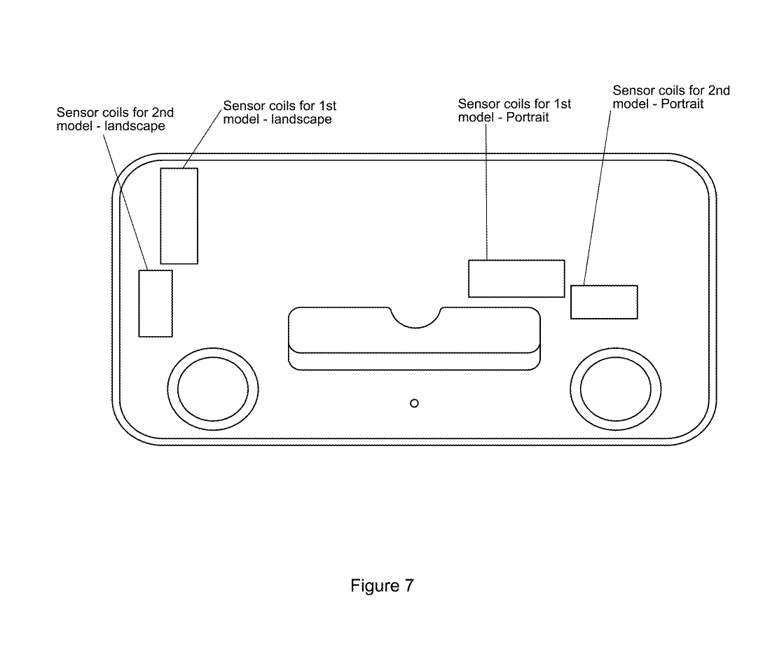

In order for the same accessory device to support more models of host devices, more than two sets of sensor coils can be built-in to the accessory device. As described in FIG. 7, two sets of sensor coils are placed in the matching positions to pick up the audio signals properly for both portrait and landscape operations for the first model of the tablet computer. Another two sets of sensor coils are positioned for the second model of the tablet computer. The sensors coils are selected by manual switching or automatic switching.

Many mobile phones have a speaker phone mode that allows hands-free operation. However the built-in speaker phone function is often not good enough for in vehicle usage. One reason is that the maximum volume of the small built-in speaker is often too low when being used in a noisy environment such as inside a moving vehicle. The second reason is that the built-in speaker is often not facing the user due to the mobile phone's position in the vehicle.

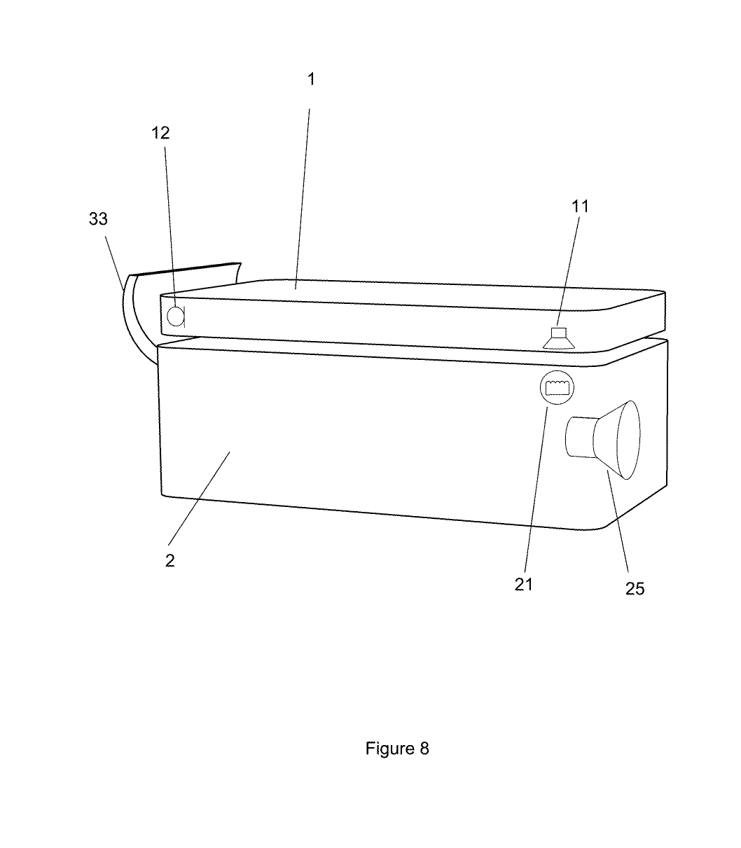

FIG. 8 describes a preferred embodiment as a hands-free car kit for mobile phones. After the mobile phone 1 is switched to speaker-phone mode, the sensor coil 21 in the hands-free car kit 2 picks up the voice signal and feeds it to the amplifying speaker. The loudspeaker 25 is mounted towards the user for the user to get a clearer reception and to avoid echo. A simple sound reflector 33 is included to amplify acoustically the sound reaching the microphone 12 of the mobile phone 1. The sound reflector increases the transmitting sensitivity of the entire speaker phone system.

Although most ready-made portable devices 1 do not have built-in components specifically for use with the accessory devices described here, dedicated inductive transmitters can be incorporated into host devices from the design stage.

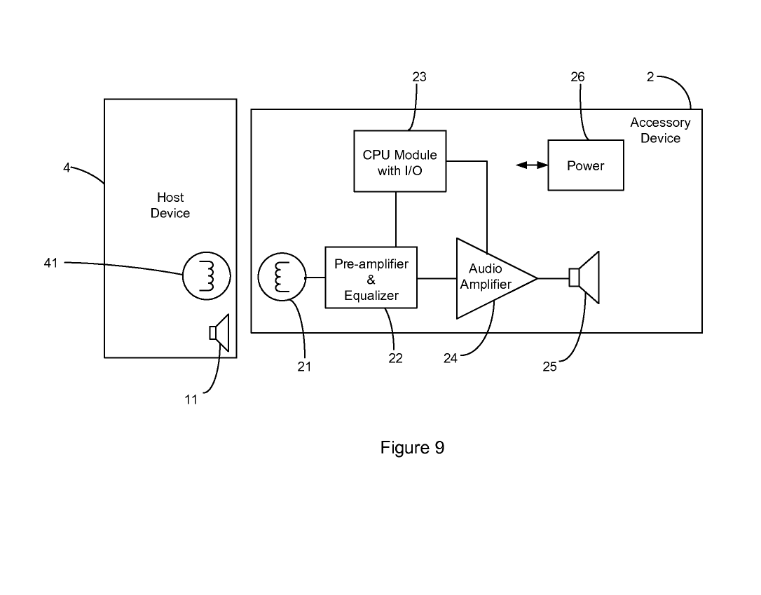

FIG. 9 describes a host device 4 with a dedicated built-in transmitter coil 41 that couples the audio signal to the sensor coil 21 in the accessory device. The transmitter coil 41 can be connected to the loudspeaker 11 in parallel to transmit whatever signal which is passed to the loudspeaker 11. In this case, the resistance of the transmitter is a few times greater than the built-in loudspeaker's so as to not affect much the performance of the loudspeaker.

For better performance, the transmitter coil can be driven by a separated amplifier that can be controlled by a CPU module inside the host device. The transmitter coil can also be used as an input sensor to receive audio signal and/or encoded audio signal to form a two way inductive communication system between a host and an accessory, or between two hosts.

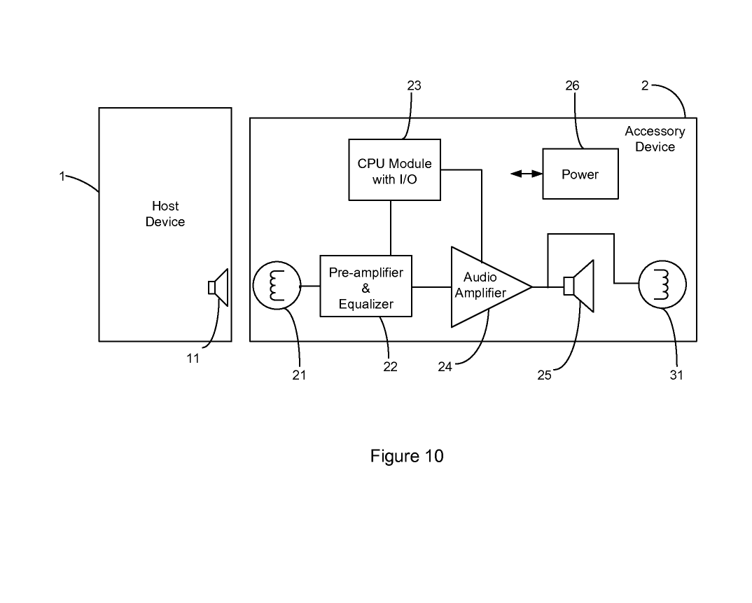

FIG. 10 describes a preferred embodiment in which a transmitter coil 31 is added in the accessory device. With the added transmitter coil 1, a second accessory device can be linked to the first accessory device wirelessly. A third accessory device can be linked to the second accessory device wirelessly, and so on, forming a chain to work together. The phases of the transmitted signal need to be coordinated correctly to ensure that the sound coming out from different accessory devices adds up instead of interfering with each other.

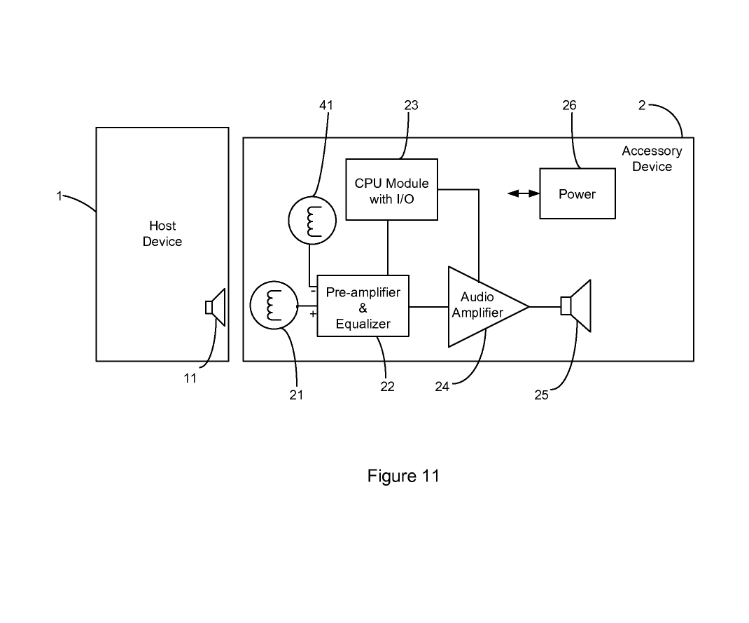

Sensor coil 21 can pick up environmental electro-magnetic noises. For example power lines or transformers nearby can generate noises in the audible frequency range. Generators or motors nearby can also generate audible electro-magnetic noises. In order to minimize this kind of noise, a noise cancellation sensor coil 41 is added as described in FIG. 11. The noise cancellation sensor coil 41 is positioned physically in parallel to the main sensor coil 21, but far away from the host device's internal speaker 11. The two sensor coils are connected to the pre-amplifier 22 in a subtractive way. The noise signals received from sensor coil 21 and from sensor coil 41 are almost the same, so they cancel out each other. Because the noise cancellation sensor coil 41 is not close to the host device's internal speaker 11, the intended electro-magnetic audio signal is received only by the sensor coil 21 and will not be cancelled out.

When comparing to wireless digital audio transmission means, one of the significant advantages of the inductive audio coupling mechanism is that receiver requires little power. The other advantage is that no configuration process for the user is needed. The third advantage is the low cost as transmitter and receiver are essentially coils. The disadvantage is that the frequency response is poorer, distortion can be greater and S/N ratio can be lower than digital systems. However, in many portable applications such as portable speakers, the lack of sound quality is compensated by the other advantages.

The inductive coupling means can also be used together with the existing wireless digital transmission means such as Bluetooth or wired cable to form a higher quality amplifying speaker.

The built-in speaker system inside the host unit can be mono or stereo. The accessory device can also be mono or stereo. This description uses mono examples. For a stereo configuration, all the sensors coils, and amplifiers and speakers will have two channels.

The present invention may be embodied in other specific forms without departing from its spirit or essential characteristics. The described embodiments are to be considered in all respects only as illustrative and not restrictive.

What is claimed is:

1. An amplifying loudspeaker apparatus for an existing host device having not been designed or made to use inductive coupling via its internal loudspeaker for audio transmission, comprising: a sensor coil located close to said internal loudspeaker for receiving an audio signal in electromagnetic form from said internal loudspeaker; a pre-amplifier and equalizer module connected to said sensor coil for amplifying and equalizing said audio signal to a suitable level and frequency response; and an audio power amplifier and loudspeaker to reproduce a sound for said audio signal; a power module for supplying power.

2. The apparatus according to claim 1, comprising a CPU module connected with said pre-amplifier module and said audio power amplifier module for detecting if there is an audio signal received from said sensor coil and for turning said power amplifier module on or off according to the detection.

3. The apparatus according to claim 1, comprising two or more of said sensor coils to work with different kinds of existing host devices.

4. The apparatus according to claim 3, comprising a multi-channel switch for selection of the correct sensor coil or coils for a particular host device in a particular location.

5. The apparatus according to claim 4, wherein said multi-channel switch is a manual switch.

6. The apparatus according to claim 4, wherein said multi-channel switch is an electronic switch controlled by said CPU module.

7. The apparatus according to claim 1, wherein said sensor coil is removable so as to be positioned close to said internal speaker of said host device.

8. The apparatus according to claim 1, comprising a transmitting coil for transmitting said audio signal to another amplifying loudspeaker apparatus.

9. The apparatus according to claim 1, comprising a sound reflector for reflecting the voice from a user to said host device's microphone during a hands-free phone call.

10. The apparatus according to claim 1, comprising a noise cancellation coil located far way from said host device's built-in speaker but connected with said sensor coil in a subtractive way.
